(19) United States
(12) Patent Application Publication
(10) Pub. No.: US 2024/0333395 A1
(43) Pub. Date: Oct. 3, 2024

(54) WAVELENGTH-TUNABLE LIGHT SOURCE DEVICE, OPTICAL TRANSCEIVER, AND WAVELENGTH CONTROL METHOD

(71) Applicant: NEC Corporation, Tokyo (JP)

(72) Inventor: Atsushi KOZATO, Tokyo (JP)

(73) Assignee: NEC Corporation, Tokyo (JP)

(21) Appl. No.: 18/409,889

(22) Filed: Jan. 11, 2024

(30) Foreign Application Priority Data
Mar. 30, 2023 (JP) 2023-056720

(51) Int. Cl. H04B 10/572; H01S 5/0625; H01S 5/125; H04B 10/50

(52) U.S. Cl. CPC H04B 10/572; H01S 5/06256; H01S 5/125; H04B 10/506

(57) ABSTRACT

An object is to control the wavelength of a light output from a wavelength-tunable light source device with high precision. A light source outputs a light. A wavelength filter transmits a light having a wavelength being a part of a wavelength included in the light output from the light source. A transmission characteristics adjustment unit can adjust transmission characteristics of the wavelength filter. A control unit controls the transmission characteristics adjustment unit. A wavelength detection unit detects a wavelength of the light transmitted by the wavelength filter. The control unit feedback-controls adjustment of the transmission characteristics of the wavelength filter in the transmission characteristics adjustment unit to cause the wavelength detected by the wavelength detection unit to be a value within a predetermined range including a target wavelength.

### INCORPORATION BY REFERENCE

This application is based upon and claims the benefit of priority from Japanese patent application No. 2023-56720, filed on Mar. 30, 2023, the disclosure of which is incorporated herein in its entirety by reference.

### TECHNICAL FIELD

The present disclosure relates to a wavelength-tunable light source device, an optical transceiver, and a wavelength control method.

### BACKGROUND ART

In optical communication, an optical transceiver for transmitting an optical signal is used and a desired wavelength to be output is instructed to the optical transceiver. Such an optical transceiver stores parameters associated with the desired wavelengths in advance, and applies the parameters to a wavelength-tunable light source device to output a light having a wavelength to be output. Such various wavelength-tunable light source devices that can adjust the wavelength of an output light and methods for controlling the wavelength-tunable light source devices have been proposed (International Patent Publication No. WO 2019/160064, Japanese Unexamined Patent Application Publication Nos. 2005-327881 and H6-237242).

### SUMMARY

However, when the desired wavelength to be output is set using only the parameters stored in the transceiver as described above, a wavelength of the light that has been actually output may deviate from the desired wavelength. It has not been possible to match the wavelength of the light output from the wavelength-tunable light source device to the instructed desired wavelength with high precision.

The present disclosure has been made in view of the aforementioned circumstances, and an object of the present disclosure is to control the wavelength of a light output from a wavelength-tunable light source device with high precision.

An aspect of the present disclosure is a wavelength-tunable light source device including: a light source configured to output a light; a wavelength filter configured to transmit a light having a wavelength being a part of a wavelength included in the light output from the light source; transmission characteristics adjustment means capable of adjusting transmission characteristics of the wavelength filter; control means for controlling the transmission characteristics adjustment means; and wavelength detection means for detecting a wavelength of the light transmitted by the wavelength filter, in which the control means feedback-controls adjustment of the transmission characteristics of the wavelength filter in the transmission characteristics adjustment means to cause the wavelength detected by the wavelength detection means to be a value within a predetermined range including a target wavelength.

An aspect of the present disclosure is an optical transceiver including: a wavelength-tunable light source device; and an optical modulator configured to output an optical signal generated by modulating a light output from the wavelength-tunable light source device, in which the wavelength-tunable light source device includes: a light source configured to output a light; a wavelength filter configured to transmit a light having a wavelength being a part of a wavelength included in the light output from the light source; transmission characteristics adjustment means capable of adjusting transmission characteristics of the wavelength filter; control means for controlling the transmission characteristics adjustment means; and wavelength detection means for detecting a wavelength of the light transmitted by the wavelength filter, and the control means feedback-controls adjustment of the transmission characteristics of the wavelength filter in the transmission characteristics adjustment means to cause the wavelength detected by the wavelength detection means to be a value within a predetermined range including a target wavelength.

An aspect of the present disclosure is a wavelength control method including: by a wavelength filter, transmitting a light having a wavelength being a part of a wavelength included in a light output from a light source; detecting a wavelength of the light transmitted by the wavelength filter; and feedback-controlling the adjustment of transmission characteristics of the wavelength filter to cause the detected wavelength to be a value within a predetermined range including a target wavelength.

According to the present disclosure, it is possible to control the wavelength of a light output from a wavelength-tunable light source device with high precision.

### BRIEF DESCRIPTION OF DRAWINGS

The above and other aspects, features and advantages of the present disclosure will become more apparent from the following description of certain exemplary embodiments when taken in conjunction with the accompanying drawings, in which:

FIG. 1 schematically illustrates an optical communication system according to a first example embodiment;

FIG. 2 schematically illustrates a configuration of an optical transceiver according to the first example embodiment;

FIG. 3 schematically illustrates a configuration of an optical transmitter according to the first example embodiment;

FIG. 4 schematically illustrates a configuration of a wavelength-tunable light source device according to the first example embodiment;

FIG. 5 illustrates the configuration of the wavelength-tunable light source device in more detail;

FIG. 6 illustrates an example of transmission characteristics of a detection wavelength filter held by a wavelength detection unit;

FIG. 7 shows a flow chart of feedback-control of the wavelength of an output light in the wavelength-tunable light source device;

FIG. 8 illustrates a relation between power supplied to heaters and the wavelength of the output light;

FIG. 9 schematically illustrates a configuration of an optical communication system according to a second example embodiment;

FIG. 10 schematically illustrates a configuration of a wavelength-tunable light source device according to the second example embodiment; and

FIG. 11 illustrates a flow chart of a wavelength control operation of the output light in the wavelength-tunable light source device according to the second example embodiment.

### EXAMPLE EMBODIMENTS

Example embodiments of the present disclosure will be described below with reference to the drawings. In each of the drawings, the same elements will be denoted by the same reference signs, and duplicate description will be omitted as necessary.

### First Example Embodiment

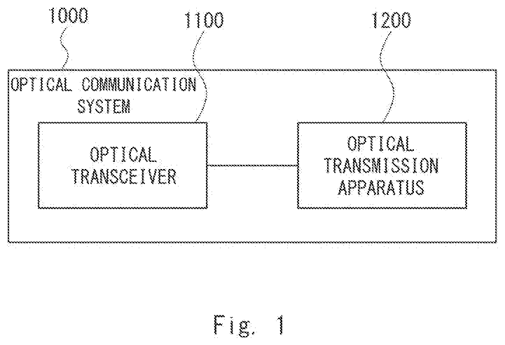

An optical communication system 1000 according to a first example embodiment will be described. FIG. 1 schematically illustrates an optical communication system 1000 according to the first example embodiment. An optical communication system 1000 includes an optical transmission apparatus 1200 and an optical transceiver 1100. The optical transmission apparatus 1200 is a communication host. The optical transceiver 1100 is connected to the optical transmission apparatus 1200 and preforms transmission and reception of an optical signal.

The optical transceiver 1100 configured, for example, as a SFP (Small Form Factor Pluggable) optical transceiver that is a pluggable optical transceiver insertable into and removable from the optical transmission apparatus 1200. The optical transceiver 1100 is provided with an electric connector and attached to the optical transmission apparatus 1200 by inserting the electric connector into the optical transmission apparatus 1200.

The optical transmission apparatus 1200 includes a digital signal processing unit that is configured as an electric circuitry such as an IC (Integrated Circuit), for example. The digital signal processing unit performs communication data processing such as frame processing on communication data signals from the optical transceiver 1100 or communication data signals input to the optical transceiver 1100.

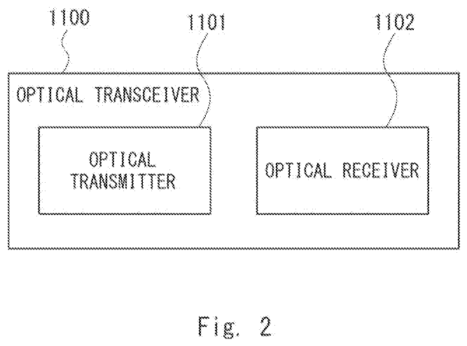

The optical transceiver 1100 will be described. FIG. 2 schematically illustrates a configuration of the optical transceiver 1100 according to the first example embodiment. The optical transceiver 1100 includes an optical transmitter 1101 that transmits a modulated optical signal and an optical receiver 1102 that receives a modulated optical signal transmitted from the outside. For example, the optical transmitter 1101 is configured to be able to transmit an optical signal that has been modulated based on a data signal input from the optical transmission apparatus 1200 that is the communication host to another optical transceiver or the like. The optical receiver 1102 is configured to be able to output a data signal that has been demodulated from an optical signal received from the other optical transceiver to the optical transmission apparatus 1200 that is the communication host.

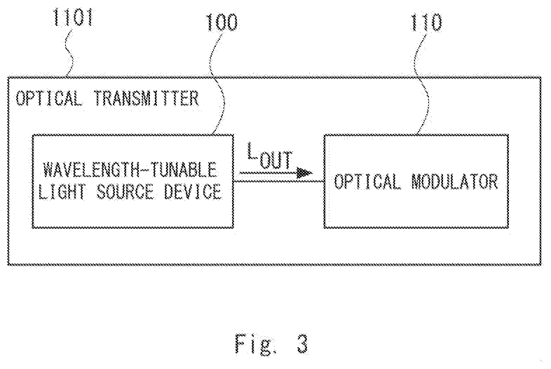

The optical transmitter 1101 will be described. FIG. 3 schematically illustrates a configuration of the optical transmitter 1101 according to the first example embodiment. The optical transmitter 1101 includes a wavelength-tunable light source device 100 and an optical modulator 110. The wavelength-tunable light source device 100 is a light source device that can adjust the wavelength of an output light L_{OUT}. The optical modulator 110 outputs an optical signal obtained by modulating the output light L_{OUT} from the wavelength-tunable light source device 100 with a predetermined modulation scheme.

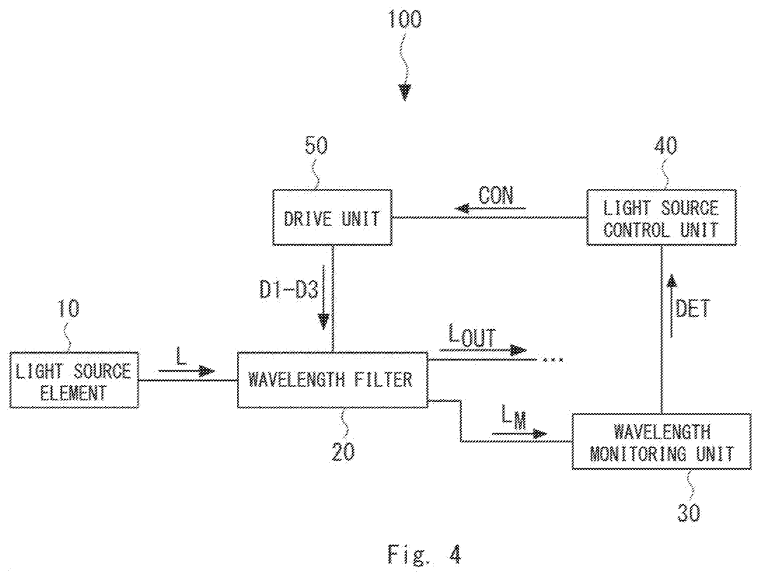

The wavelength-tunable light source device 100 will be described. FIG. 4 schematically illustrates a configuration of the wavelength-tunable light source device 100 according to the first example embodiment. The wavelength-tunable light source device 100 includes a light source element 10, a wavelength filter 20, a wavelength monitoring unit 30, a light source control unit 40, and a drive unit 50.

The light source element 10 is configured as a device outputting a light L, for example, as a semiconductor laser device such as a DFB (Distributed Feedback) laser device that outputs a laser light of a non-modulated continuous wave as the light L.

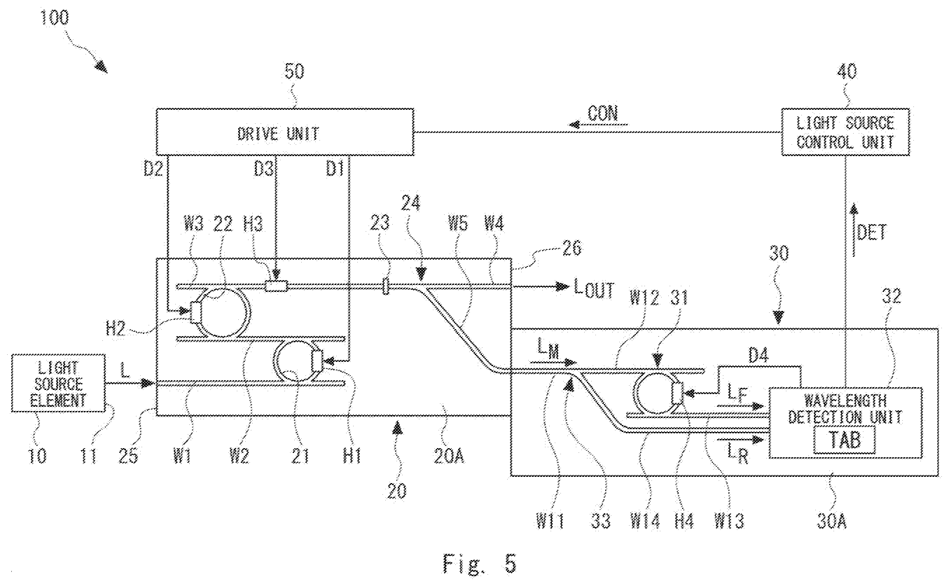

The wavelength filter 20 is a wavelength filter that selectively transmits a light of a specific wavelength in the light L output from the light source element 10. FIG. 5 illustrates the configuration of the wavelength-tunable light source device 100 in more detail.

The wavelength filter 20 is configured as an external resonator that can resonate the light L output from the light source element 10 to cause laser oscillation, and can adjust a wavelength and phase of the oscillated light. The wavelength filter 20 can be configured, for example, as a semiconductor device manufactured by a silicon (Si) photonics technology and can be manufactured, for example, by the known Si process such as a CMOS (Complementary Metal Oxide Semiconductor) process.

A configuration of the wavelength filter 20 will be described. In wavelength filter 20, ring resonators 21 and 22, a half mirror 23, a coupler 24, optical waveguides W1 to W5, and heaters H1 to H3 are formed on a substrate 20A. The substrate 20A is a silicon substrate or a SOI (Silicon on Insulator) substrate, for example. The ring resonators 21 and 22 are also referred to as first and second ring resonators, respectively. The heater H1 and H2 are also referred to as first and second heaters, respectively.

The optical waveguides W1 to W5 are composed of silicon wire waveguides or rib waveguides, for example. The optical waveguide W1 optically connects an entrance face 25 and the ring resonator 21. The optical waveguide W2 optically connects the ring resonator 21 and the ring resonator 22. The optical waveguide W3 optically connects the ring resonator 22 and the half mirror 23. The light L output from the light source element 10 is incident on the ring resonator 21 through the optical waveguide W1.

The ring resonators 21 and 22 function as wavelength filters that can change the wavelength of a transmitted light. When the light resonates between the ring resonators 21 and 22, laser oscillation occurs. The ring resonators 21 and 22 are provided with the heaters H1 and H2, respectively. A refractive index of the optical waveguide forming the ring resonator 21 changes by heating the optical waveguide with the heater H1, thereby controlling the wavelength of the transmitted light of the ring resonator 21. Similarly, a refractive index of the optical waveguide forming the ring resonator 22 changes by heating the optical waveguide with the heater H2, thereby controlling the wavelength of the transmitted light of the ring resonator 22. When the wavelengths of the transmitted lights of the ring resonators 21 and 22 match, a light of the matched wavelength causes laser oscillation.

The optical waveguide W3 between the half mirror 23 and the ring resonator 22 is provided with the heater H3. A refractive index of the optical waveguide W3 changes by heating it with the heater H3, and as a result, an optical length of a resonator (length of the resonator) configured between an end face 11 of the light source element 10 and the half mirror 23 changes. Thus, a phase of the light output from the wavelength filter 20, that is, the phases of the output light L_{OUT} and a monitor light L_{M} described later, can be controlled.

For example, by adjusting the phase of the light reciprocating in the resonator between the end face 11 of the light source element 10 and the half mirror 23 with the heater H3 so that the phase is in a positive feedback state, the laser oscillation can be continued and the amplification of the oscillated light can be maximized.

The heaters H1 to H3 are controlled by drive signals D1 to D3 output from the drive unit 50, respectively. The drive signals D1 to D3 are current signals, and the degrees of heating of the optical waveguides by the heaters H1 to H3, that is, the refractive indices of the waveguides can be adjusted. The drive signals D1 and D2 are also referred to as first and second drive signals, respectively.

Most of the light transmitted through the half mirror 23 is coupled to the optical waveguide W4 by the coupler 24, and then output to the optical modulator 110 as the output light L_{OUT}. A part of the light transmitted through the half mirror 23 other than the light coupled to the optical waveguide W4 is coupled to the optical waveguide W5, and then output to the wavelength monitoring unit 30 as the monitor light L_{M}.

According to the above-described configuration, by amplifying only the light of the desired wavelength by the ring resonators 21 and 22, and transmitting the light through the half mirror 23, the laser light of the desired wavelength can be output from an exit face 26 as the output light L_{OUT} and the monitor light L_{M}.

The wavelength monitoring unit 30 detects the wavelength of the monitor light L_{M} and outputs a detection signal DET indicating a monitoring result. The wavelength monitoring unit 30 includes a detection wavelength filter 31, a wavelength detection unit 32, and a coupler 33. The wavelength detection unit 32 is also referred to as wavelength detection means. The wavelength monitoring unit 30 can be configured, for example, as a semiconductor device formed on a substrate 30A composed of silicon by the silicon (Si) photonics technology as in the case of the wavelength filter 20.

The monitor light L_{M} propagates through an optical waveguide W11 and enters the coupler 33. The coupler 33 branches the monitor light L_{M} and most of the monitor light L_{M} is output to the detection wavelength filter 31 through an optical waveguide W12. A part of the monitor light L_{M} is output to the wavelength detection unit 32 through an optical waveguide W14 as a reference light LR.

The detection wavelength filter 31 outputs a filtered monitor light L_{F} obtained by wavelength-filtering the monitor light L_{M} input through the optical waveguide W12 to the wavelength detection unit 32 through an optical waveguide W13.

The wavelength detection unit 32 calculates a light intensity PD1 of the monitor light L_{M} input to the detection wavelength filter 31 based on the input reference light LR. Since a branch ratio of the monitor L_{M} in the coupler 33 has been previously known, from the branch ratio and the intensity of the reference light LR, the light intensity PD1 of the monitor light L_{M} input to the detection wavelength filter 31 can be easily calculated.

Then, the wavelength detection unit 32 detects the wavelength of the monitor light L_{M} from an intensity ratio PD2/PD1 of a light intensity PD2 of the filtered monitor light L_{F} to the light intensity PD1 of the monitor L_{M} that has been calculated. Hereinafter, the intensity ratio PD2/PD1 is referred to as an input/output ratio R.

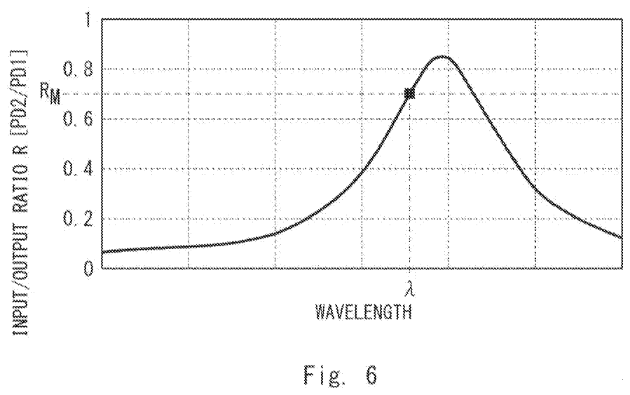

The wavelength detection unit 32 holds information indicating transmission characteristics of the detection wavelength filter 31 in advance. The wavelength detection unit 32 holds, for example, information indicating a relation between the input/output ratio R and the wavelength as the information indicating the transmission characteristics of the detection wavelength filter 31. FIG. 6 illustrates an example of the transmission characteristics of the detection wavelength filter 31 held by the wavelength detection unit 32. In this example, the horizontal axis denotes the wavelength of the monitor light L_{M} and the vertical axis denotes the input/output ratio R.

The wavelength detection unit 32 holds the relation between the input/output ratio R and the wavelength illustrated in FIG. 6, for example, as table information. The wavelength detection unit 32 can identify the wavelength of the monitor light L_{M} by comparing a measured input/output ratio RM with the table information. In the example of FIG. 6, the wavelength detection unit 32 detects a wavelength λ corresponding to the measured input/output ratio RM as the wavelength of the monitor light L_{M}.

Note that, as in the case of the ring resonators 21 and 22, by providing a heater to the detection wavelength filter 31, a refractive index thereof can be also adjusted. Here, an example in which a heater H4 is provided to the detection wavelength filter 31 will be described. A refractive index of a waveguide forming the detection wavelength filter 31 changes by heating the waveguide with the heater H4, and thereby controlling the wavelength of the transmitted light of the detection wavelength filter 31. Thus, the transmission characteristics of the detection wavelength filter 31 can be controlled.

For example, when the wavelength of the monitor light L_{M} to be detected does not match the transmission characteristics of the detection wavelength filter 31, it is conceivable that the light intensity of the filtered monitor light L_{F} becomes weak. In this case, the above-described wavelength detection cannot be performed. To avoid such a situation, the transmission characteristics of the detection wavelength filter 31 may be adjusted to cause the detection wavelength filter 31 to appropriately transmit the monitor light L_{M}, for example, by providing a drive signal D4 to the heater H4 from the wavelength detection unit 32.

To adjust the refractive index of the detection wavelength filter 31, information indicating a correspondence relation between the drive signal D4 and the transmission characteristics of the detection wavelength filter 31 may be held as table information in advance, and the drive signal D4 may be provided to the heater H4 with reference to the table information, for example. Further, to perform the wavelength detection based on the input/output ratio R, information indicating a correspondence relation between the input/output ratio R and the wavelength, and the transmission characteristics of the detection wavelength filter 31 or the drive signal D4 may be held as table information in advance, and the wavelength detection may be performed with reference to the table information, for example.

As described above, the detection wavelength filter 31 can be controlled by providing the heater to the detection wavelength filter 31, and a detectable wavelength range can be also expanded.

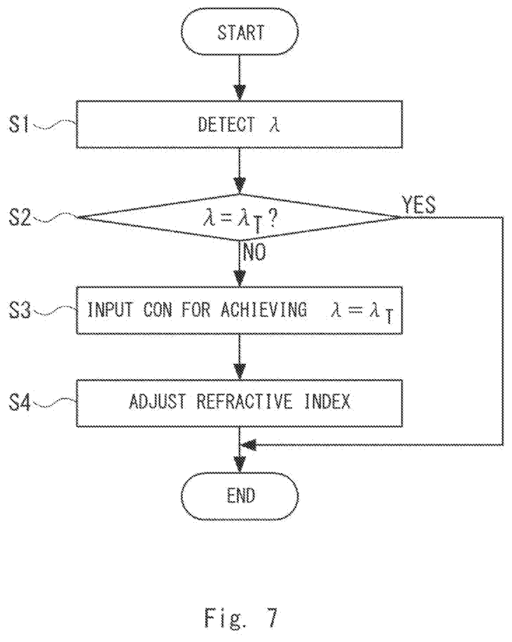

Next, feedback-control of the output light in the wavelength-tunable light source device 100 according to the present example embodiment will be described. FIG. 7 shows a flow chart of the feedback-control of the wavelength of the output light in the wavelength-tunable light source device 100. The wavelength-tunable light source device 100 performs the feedback-control of the wavelength of the output light by processes of Steps S1 to S4 shown in FIG. 7.

### Step S1

The wavelength detection unit 32 detects the wavelength λ and outputs the detection signal DET to the light source control unit 40.

### Step S2

The light source control unit 40 determines whether the wavelength λ match the target wavelength λ_{T} based on the detection signal DET. To determine whether the wavelength λ match a target wavelength λ_{T}, it is not necessary that both values strictly match, and whether the wavelength λ falls within a predetermined range including the target wavelength λ_{T} may be determined. When the wavelength λ matches the target wavelength λ_{T}, the light source control unit 40 terminates the process.

### Step S3

When the wavelength λ does not match the target wavelength λ_{T}, the light source control unit 40 outputs a control signal CON to the drive unit 50 to match the wavelength λ with the target wavelength λ_{T}.

### Step S4

The drive unit 50 adjusts the drive signals D1 and D2 provided to the heaters H1 and H2 to match the wavelength λ with the target wavelength λ_{T} in response to the control signal CON. The drive signals D1 and D2 are current signals provided to the heaters H1 and H2, respectively. The drive unit 50 can control the wavelength of the light output from the wavelength filter 20 by adjusting the drive signals D1 and D2. After that, the process returns to Step S1.

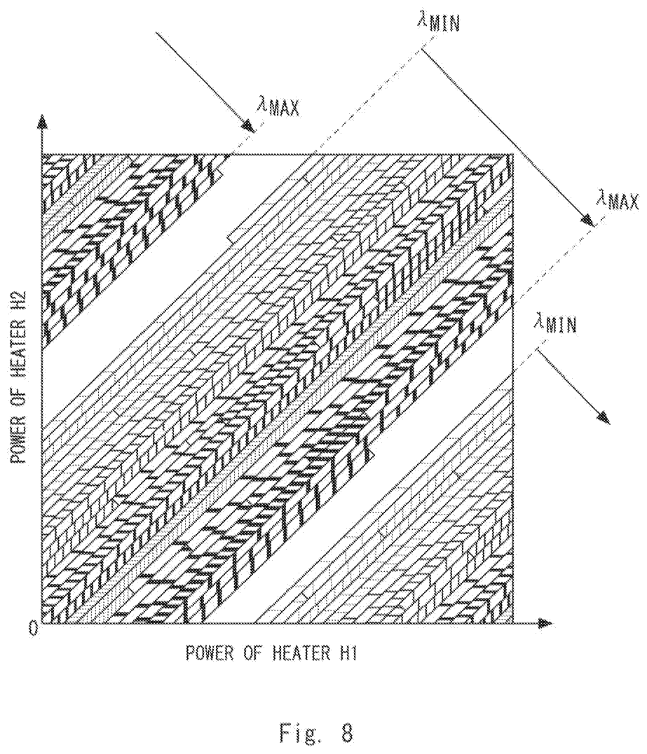

In the present example embodiment, by controlling power supplied to each of the heaters H1 and H2 provided to the ring resonators 21 and 22, the refractive indices of the waveguides forming the ring resonators 21 and 22 are adjusted, and thereby controlling the wavelength of the output light L_{OUT}. That is, the wavelength of the output light L_{OUT} is affected by both ring resonators 21 and 22. FIG. 8 illustrates a relation between the power supplied to the heaters H1 and H2 and the wavelength of the output light. As illustrated in FIG. 8, it can be understood that the wavelength of the output light changes within a desired range, for example, within a wavelength range from λ_{MIN} to λ_{MAX}, depending on both the power of the heater H1 and the power of the heater H2. In FIG. 8, each wavelength channel is illustrated by using hatching. To certainly adjust the output light to the desired wavelength, the heaters H1 and H2 can be adjusted according to the shapes and/or arrangements of the ring resonators 21 and 22 based on FIG. 8. In other words, based on FIG. 8, the heaters H1 and H2 may be adjusted based on table information indicating a correspondence relation between the output light, and the heaters H1 and H2. For example, after controlling the power of one of the heaters H1 and H2 based on the table information, the power of the other of the heaters H1 and H2 may be controlled based on the table information. Further, both heaters H1 and H2 may be concurrently controlled based on the table information.

As described above, according to the present configuration, it is possible to feedback-control the refractive index of the waveguide forming the ring resonator of the wavelength filter by monitoring the wavelength of the light output from the wavelength filter to match the wavelength of the light output from the wavelength filter with the desired wavelength. Thus, it is possible to control a wavelength of an output light of a wavelength-tunable light source device with high precision.

### Second Example Embodiment

In the first example embodiment, the feedback-control of the output light in the wavelength-tunable light source device has been described. Meanwhile, when operating the wavelength-tunable light source device, feedforward-control for initially setting the output light is firstly performed. Thus, in the present example embodiment, the feedforward-control in the above-described wavelength-tunable light source device will be described.

To perform the feedforward-control of the wavelength, the drive signals D1 and D2 having the power corresponding to the target wavelength are provided to the heaters H1 and H2, respectively. Thus, it is necessary to understand a correspondence relation between the power of the drive signals D1 and D2 provided to the heaters H1 and H2, and the wavelength of the output light in advance.

Hence, as illustrated in FIG. 8, for example, information indicating the correspondence relation between the power supplied to the heaters H1 and H2, and the wavelength of the output light may be obtained as table information in advance, and the power corresponding to the target wavelength may be supplied to the heaters H1 and H2 with reference to the table information as appropriate.

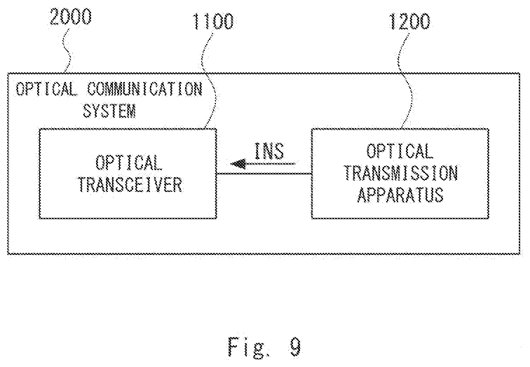

FIG. 9 schematically illustrates a configuration of an optical communication system 2000 according to a second example embodiment. The optical communication system 2000 is different from the optical communication system 1000 according to the first example embodiment in that a wavelength instruction INS specifying the wavelength of the output light is output from the optical transmission apparatus 1200 to the optical transceiver 1100.

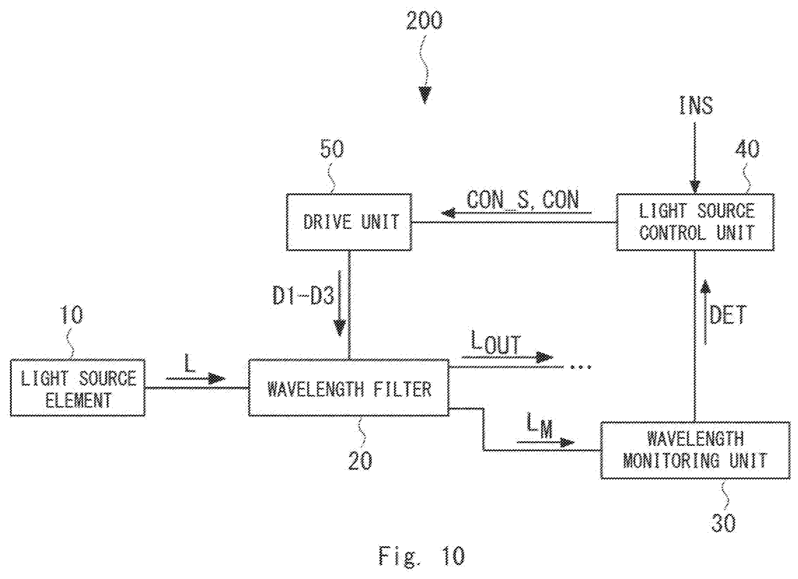

FIG. 10 schematically illustrates a configuration of a wavelength-tunable light source device 200 according to the second example embodiment. The wavelength-tunable light source device 200 has the same configuration as that of the wavelength-tunable light source device 100. However, the wavelength-tunable light source device 200 is different from the wavelength-tunable light source device 100 in that the wavelength instruction INS from the optical transmission apparatus 1200 is input to the light source control unit 40.

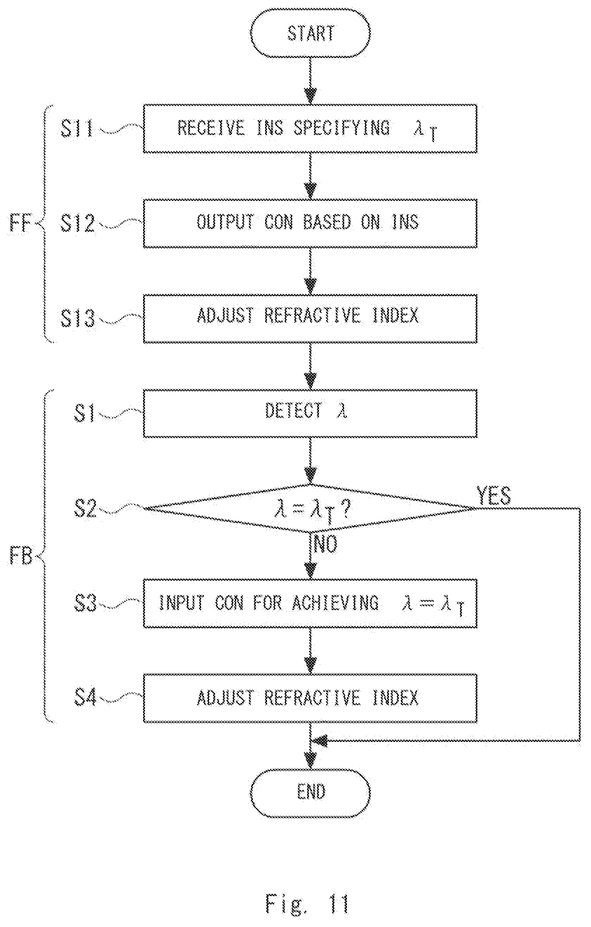

Next, a wavelength control operation of the wavelength-tunable light source device according to the second example embodiment will be described. FIG. 11 illustrates a flow chart of the wavelength control operation of the output light in the wavelength-tunable light source device 200 according to the second example embodiment. In the wavelength control operation of the output light in the present second example embodiment, Steps S11 to S13 are inserted before Steps S1 to S4 in FIG. 8.

### Step S11

The light source control unit 40 receives the wavelength instruction INS specifying the wavelength of the output light from the optical transmission apparatus 1200. Needless to say, a wavelength specified by the wavelength instruction INS is the target wavelength λ_{T}.

### Step S12

The light source control unit 40 refers to information indicating the correspondence relation between the drive signals D1 and D2, and the wavelength of the output light that has been held therein in advance, and outputs a control signal CON_S to the drive unit 50 to cause the wavelength of the output light to be the target wavelength λ_{T}. Needless to say, the control signal CON_S is a signal that specifies power values of the drive signals D1 and D2 for the drive unit 50.

### Step S13

The drive unit 50 adjusts the power values of the drive signals D1 and D2 provided to the heaters H1 and H2, and adjusts the refractive indices of the waveguides forming the ring resonators 21 and 22 in response to the control signal CON_S to cause the wavelength of the output light to be the target wavelength λ_{T}.

In Steps S11 to S13, without observing the real wavelength of the output light, the refractive indices of the waveguides forming the ring resonators 21 and 22 have been adjusted based on the wavelength instruction INS. Thus, at this time, it is unclear whether the wavelength of the output light matches the target wavelength λ_{T}. Hence, by executing the processes similar to those of Steps S1 to S4 in FIG. 8 hereinafter, the feedback-control of the wavelength of the output light is performed. The redundant descriptions of Steps S1 to S4 will be omitted.

As described above, according to the present configuration, it is possible to appropriately specify the target wavelength of the output light of the wavelength-tunable light source by the feedforward-control. After that, by monitoring the wavelength of the light output from the wavelength filter, it is further possible to feedback-control the refractive indices of the waveguides forming the ring resonators of the wavelength filter to cause the wavelength of the light to be the desired wavelength. Thus, it is possible to control the wavelength of the output light of the wavelength-tunable light source with high precision.

### Other Example Embodiments

Note that the present disclosure is not limited to the example embodiment described above, and may be appropriately modified without departing from the scope of the present disclosure. For example, although it has been described that the refractive index of the optical waveguide is adjusted by heating the optical waveguide with the heater provided on the optical waveguide, this is merely an example. The refractive index of the optical waveguide may be adjusted by various methods such as providing an electrode on the optical waveguide to inject a current or apply a voltage to the optical waveguide.

In the drawings referred to in the above-described example embodiments, the transmission of signals between components is shown using arrows, but this does not mean that signals are transmitted only in one direction between two components. It goes without saying that signals can be exchanged in both directions as appropriate.

For example, the configuration of the optical transceiver has been simplified to explain the optical transceiver. It goes without saying that various other components may be included in the optical transceiver.

The optical communication system, the optical transceiver, and the wavelength-tunable light source device according to the above-described example embodiments are not limited to the above description. Various modifications, which those skilled in the art can understand, to the optical communication system, the optical transceiver, and the wavelength-tunable light source device according to the above-described example embodiments can be made within the same scope.

The first and second embodiments can be combined as desirable by one of ordinary skill in the art.

While the disclosure has been particularly shown and described with reference to embodiments thereof, the disclosure is not limited to these embodiments.

It will be understood by those of ordinary skill in the art that various changes in form and details may be made therein without departing from the spirit and scope of the present disclosure as defined by the claims.

The whole or part of the above example embodiments can be described as, but not limited to, the following supplementary notes.

(Supplementary Note 1) A wavelength-tunable light source device including: a light source configured to output a light; a wavelength filter configured to transmit a light having a wavelength being a part of a wavelength included in the light output from the light source; transmission characteristics adjustment means capable of adjusting transmission characteristics of the wavelength filter; control means for controlling the transmission characteristics adjustment means; and wavelength detection means for detecting a wavelength of the light transmitted by the wavelength filter, in which the control means feedback-controls adjustment of the transmission characteristics of the wavelength filter in the transmission characteristics adjustment means to cause the wavelength detected by the wavelength detection means to be a value within a predetermined range including a target wavelength.

(Supplementary Note 2) The wavelength-tunable light source device according to Supplementary Note 1, in which the wavelength filter includes an optical waveguide guiding the light output from the light source, and the transmission characteristics adjustment means adjusts a refractive index of the optical waveguide to adjust the transmission characteristics of the wavelength filter.

(Supplementary Note 3) The wavelength-tunable light source device according to Supplementary Note 2, in which the wavelength filter includes: a first ring resonator and a second ring resonator each including an optical waveguide guiding the light from the light source, the transmission characteristics adjustment means, in response to feedback-control performed by the control means, provides a first drive signal to the first ring resonator to adjust a refractive index of the optical waveguide forming the first ring resonator, and provides a second drive signal to the second ring resonator to adjust a refractive index of the optical waveguide forming the second ring resonator.

(Supplementary Note 4) The wavelength-tunable light source device according to Supplementary Note 3, in which first and second heaters are provided to the first and second ring resonators, respectively, and the transmission characteristics adjustment means adjusts power supplied to the first and second heaters by the first and second drive signals.

(Supplementary Note 5) The wavelength-tunable light source device according to Supplementary Note 4, in which the control means can feedforward-control the transmission characteristics adjustment means prior to the feedback-control, in the feedforward-control, the control means can receive a wavelength instruction specifying the target wavelength, holds table information indicating a relation between power values supplied to the first and second heaters by the first and second drive signals, and a wavelength of the light transmitted by the wavelength filter in advance, and controls the transmission characteristics adjustment means to respectively supply the first and second drive signals having the power obtained by comparing the target wavelength with the table information to the first and second heaters.

(Supplementary Note 6) The wavelength-tunable light source device according to Supplementary Note 1 or 2, in which the wavelength detection means includes: a detection wavelength filter having predetermined transmission characteristics, the light transmitted by the wavelength filter is input to the detection wavelength filter, and detection means for detecting the wavelength of the light transmitted by the wavelength filter, based on the light transmitted by the wavelength filter and a light transmitted by the detection wavelength filter, the detection means calculates an input/output ratio that is a ratio of power of the light transmitted by the detection wavelength filter to power of the light transmitted by the wavelength filter that is input to the detection wavelength filter, and detects the wavelength of the light transmitted by the wavelength filter in response to the calculated input/output ratio.

(Supplementary Note 7) The wavelength-tunable light source device according to Supplementary Note 6, in which the detection means holds table information indicating a correspondence relation between the input/output ratio and the wavelength of the light transmitted by the wavelength filter in advance, and compares the calculated input/output ratio with the table information to detect the wavelength of the light transmitted by the wavelength filter.

(Supplementary Note 8) An optical transceiver including: a wavelength-tunable light source device; and an optical modulator configured to output an optical signal generated by modulating a light output from the wavelength-tunable light source device, in which the wavelength-tunable light source device includes: a light source configured to output a light; a wavelength filter configured to transmit a light having a wavelength being a part of a wavelength included in the light output from the light source; transmission characteristics adjustment means capable of adjusting transmission characteristics of the wavelength filter; control means for controlling the transmission characteristics adjustment means; and wavelength detection means for detecting a wavelength of the light transmitted by the wavelength filter, and the control means feedback-controls adjustment of the transmission characteristics of the wavelength filter in the transmission characteristics adjustment means to cause the wavelength detected by the wavelength detection means to be a value within a predetermined range including a target wavelength.

(Supplementary Note 9) An optical communication system including: an optical transceiver comprising a wavelength-tunable light source device and an optical modulator configured to output an optical signal generated by modulating a light output from the wavelength-tunable light source device; and an optical transmission apparatus to which the optical transceiver is attached, in which the wavelength-tunable light source device includes: a light source configured to output a light; a wavelength filter configured to transmit a light having a wavelength being a part of a wavelength included in the light output from the light source; transmission characteristics adjustment means capable of adjusting transmission characteristics of the wavelength filter; control means for controlling the transmission characteristics adjustment means; and wavelength detection means for detecting a wavelength of the light transmitted by the wavelength filter, and the control means feedback-controls adjustment of the transmission characteristics of the wavelength filter in the transmission characteristics adjustment means to cause the wavelength detected by the wavelength detection means to be a value within a predetermined range including a target wavelength.

(Supplementary Note 10) A wavelength control method including: by a wavelength filter, transmitting a light having a wavelength being a part a of a wavelength included in a light output from a light source; detecting a wavelength of the light transmitted by the wavelength filter; and feedback-controlling the adjustment of transmission characteristics of the wavelength filter to cause the detected wavelength to be a value within a predetermined range including a target wavelength.

What is claimed is:

1. A wavelength-tunable light source device comprising:
a light source configured to output a light;
a wavelength filter configured to transmit a light having a wavelength being a part of a wavelength included in the light output from the light source;
transmission characteristics adjustment means capable of adjusting transmission characteristics of the wavelength filter;
control means for controlling the transmission characteristics adjustment means; and
wavelength detection means for detecting a wavelength of the light transmitted by the wavelength filter, wherein
the control means feedback-controls adjustment of the transmission characteristics of the wavelength filter in the transmission characteristics adjustment means to cause the wavelength detected by the wavelength detection means to be a value within a predetermined range including a target wavelength.

2. The wavelength-tunable light source device according to claim 1, wherein
the wavelength filter comprises an optical waveguide guiding the light output from the light source, and
the transmission characteristics adjustment means adjusts a refractive index of the optical waveguide to adjust the transmission characteristics of the wavelength filter.

3. The wavelength-tunable light source device according to claim 2, wherein
the wavelength filter comprises a first ring resonator and a second ring resonator each including an optical waveguide guiding the light from the light source;
the transmission characteristics adjustment means, in response to feedback-control performed by the control means
provides a first drive signal to the first ring resonator to adjust a refractive index of the optical waveguide forming the first ring resonator, and
provides a second drive signal to the second ring resonator to adjust a refractive index of the optical waveguide forming the second ring resonator.

4. The wavelength-tunable light source device according to claim 3, wherein
first and second heaters are provided to the first and second ring resonators, respectively, and
the transmission characteristics adjustment means adjusts power supplied to the first and second heaters by the first and second drive signals.

5. The wavelength-tunable light source device according to claim 4, wherein
the control means can feedforward-control the transmission characteristics adjustment means prior to the feedback-control,
in the feedforward-control, the control means
can receive a wavelength instruction specifying the target wavelength,
holds table information indicating a relation between power values supplied to the first and second heaters by the first and second drive signals, and a wavelength of the light transmitted by the wavelength filter in advance, and
controls the transmission characteristics adjustment means to respectively supply the first and second drive signals having the power obtained by comparing the target wavelength with the table information to the first and second heaters.

6. The wavelength-tunable light source device according to claim 1, wherein
the wavelength detection means comprises:
a detection wavelength filter having predetermined transmission characteristics, the light transmitted by the wavelength filter is input to the detection wavelength filter; and
detection means for detecting the wavelength of the light transmitted by the wavelength filter, based on the light transmitted by the wavelength filter and a light transmitted by the detection wavelength filter,
the detection means
calculates an input/output ratio that is a ratio of power of the light transmitted by the detection wavelength filter to power of the light transmitted by the wavelength filter that is input to the detection wavelength filter, and
detects the wavelength of the light transmitted by the wavelength filter in response to the calculated input/output ratio.

7. The wavelength-tunable light source device according to claim 6, wherein
the detection means
holds table information indicating a correspondence relation between the input/output ratio and the wavelength of the light transmitted by the wavelength filter in advance, and
compares the calculated input/output ratio with the table information to detect the wavelength of the light transmitted by the wavelength filter.

8. An optical transceiver comprising:
a wavelength-tunable light source device; and
an optical modulator configured to output an optical signal generated by modulating a light output from the wavelength-tunable light source device, wherein
the wavelength-tunable light source device comprises:
a light source configured to output a light;
a wavelength filter configured to transmit a light having a wavelength being a part of a wavelength included in the light output from the light source;
transmission characteristics adjustment means capable of adjusting transmission characteristics of the wavelength filter;
control means for controlling the transmission characteristics adjustment means; and
wavelength detection means for detecting a wavelength of the light transmitted by the wavelength filter, and
the control means feedback-controls adjustment of the transmission characteristics of the wavelength filter in the transmission characteristics adjustment means to cause the wavelength detected by the wavelength detection means to be a value within a predetermined range including a target wavelength.

9. A wavelength control method comprising:
by a wavelength filter, transmitting a light having a wavelength being a part of a wavelength included in a light output from a light source;
detecting a wavelength of the light transmitted by the wavelength filter; and
feedback-controlling the adjustment of transmission characteristics of the wavelength filter to cause the detected wavelength to be a value within a predetermined range including a target wavelength.
